(19) United States
(12) Patent Application Publication
(10) Pub. No.: US 2010/0109703 A1
(43) Pub. Date: May 6, 2010

(54) OUTPUT CONTROL CIRCUIT

(75) Inventor: Daisuke MATSUOKA, Kyoto (JP)

Correspondence Address: MCDERMOTT WILL & EMERY LLP, 600 13TH STREET, NW, WASHINGTON, DC, 20005-3096, US

(73) Assignee: Panasonic Corporation, Osaka (JP)

(21) Appl. No.: 12/686,274

(22) Filed: Jan. 12, 2010

Related U.S. Application Data
(62) Division of application No. 11/826,106, filed on Jul. 12, 2007.

(30) Foreign Application Priority Data
Jul. 13, 2006 (JP) P. 2006-192795

(51) Int. Cl. H03K 19/00; H03K 19/20

(52) U.S. Cl. 326/56; 326/104

(57) ABSTRACT

To provide an output control circuit having a small circuit scale that still operates stably at high speed, an output control circuit includes a first inverter and a second inverter, connected in series for outputting signals at an inverted voltage level of an input signal, a first output unit, for which output is controlled based on a voltage level of a signal output by the second inverter, a third inverter, an output of which is connected to an output of the first inverter, for outputting a signal at an inverted voltage level of a signal output by the second inverter, and a second output unit for which output is controlled based on a voltage level of a signal output by the first inverter and a voltage level of a signal output by the third inverter.

### BACKGROUND OF THE INVENTION

1. Field of the Invention

The present invention relates to an output control circuit used for an interface employing a differential signal.

2. Description of the Related Art

The processing speeds of CPUs or integrated circuits included in electronic apparatuses have increased. In accordance with this speed development, data transfer rates between circuits included in an electronic apparatus or between electronic apparatuses have also increased, and to facilitate the performance of the data transfer process, interface circuits are provided for circuits or for those electronic apparatuses that transfer data. An example interface circuit is disclosed in JP-A-2001-53598; the circuit diagram for the transmitter of the interface circuit disclosed in this publication is shown in FIG. 13.

The transmitter of the interface circuit shown in FIG. 13 includes one input terminal, two output terminals OUT1 and OUT2, two inverters INV1 and INV2 connected in series, and two output transistors, the gates of which are connected to the output terminals of the inverters INV1 and INV2. In this transmitter, the output transistors are rendered on or off in accordance with the voltage levels of signals output by the inverters INV1 and INV2. And in consonance with the ON/OFF state of the output transistors, a signal is selectively output through the output terminals OUT1 and OUT2.

Patent Document 1: JP-A-2001-053598

The operating rate of the above described interface circuit is limited in accordance with a delay difference between differential signals. This limitation is imposed because, when the operating cycle of the interface is shorter than a delay difference between the differential signals, a signal error may occur and an erroneous operation may be performed.

The delay difference between differential signals is affected by the delay time of an inverter. And since micromachining for the semiconductor manufacturing process has been developed, manufacturing discrepancies and deterioration of the functions of transistors tend to be increased. Therefore, when an individual difference and fluctuation of the individual difference affected by the delay time of the inverter are great, the delay difference between differential signals also becomes great. In such a case, when an interface circuit is operated at high speed, stabilization of the operation is difficult.

One method for resolving this problem is to increase the transistor size of the inverter. However, when the transistor size is increased, this is accompanied by an increase in the scale of the interface circuit. Therefore, there is a demand for an output control circuit having a small circuit scale that still operates stably at high speed.

### SUMMARY OF THE INVENTION

One objective of the present invention is to provide an output control circuit having a small circuit scale that still operates stably at high speed.

The present invention provides an output control circuit comprising:

a first inverter and a second inverter, connected in series, for outputting signals at an inverted voltage level of an input signal;

a first output unit, for which output is controlled based on a voltage level of a signal output by the second inverter;

a third inverter, an output of which is connected to an output of the first inverter, for outputting a signal at an inverted voltage level of a signal output by the second inverter; and

a second output unit, for which output is controlled based on a voltage level of a signal output by the first inverter and a voltage level of a signal output by the third inverter.

The present invention also provides an output control circuit comprising:

a first inverter and a second inverter, connected in series, for outputting signals at an inverted voltage level of an input signal;

a first buffer, for outputting a signal at a voltage level of a signal output by the first inverter;

a first output unit, for which output is controlled based on the voltage level of the signal output by the first buffer;

a third inverter, an output of which is connected to an output of the second inverter, for outputting a signal at an inverted voltage level of a signal output by the first buffer; and

a second output unit, for which output is controlled based on a voltage level of a signal output by the second inverter and a voltage level of a signal output by the third inverter.

According to the output control circuit, one of the first to the third inverters includes a NAND gate or a NOR gate, and receives a signal different from the input signal.

According to the output control circuit, one of the first to the third inverters, or the first buffer, includes a NAND gate or a NOR gate, and receives a signal different from the input signal.

According to the output control circuit, CMOS inverters are employed as inverters whose output sides are directly connected to the first output unit and as inverters whose output sides are directly connected to the second output unit.

According to the output control circuit, the third inverter is a tri-state inverter for which output impedance is controlled based on a control signal.

According to the output control circuit, the third inverter is a switch whose output current capacity is controlled based on a control signal.

According to the output control circuit, the third inverter is arranged between the inverter whose output is directly connected to the first output unit and the inverter whose output is directly connected to the second output unit.

According to the output control circuit, the inverter whose output is directly connected to the first output unit is arranged so as to be nearer the first output unit than the inverter, whose output is directly connected to the second output unit, or the third inverter.

According to the output control circuit, the inverter whose output is directly connected to the second output unit is arranged so as to be nearer the second output unit than the inverter, whose output is directly connected to the first output unit, or the third inverter.

The output control circuit further comprises:

a first pad connected to an output terminal of the first output unit; and

a second pad connected to an output terminal of the second output unit,

wherein the first pad and the second pad are adjacently arranged.

According to the present invention, an output control circuit having a small circuit scale can be provided that still operates stably at high speed.

### BRIEF DESCRIPTION OF THE DRAWINGS

FIG. 1 is a circuit diagram showing an output control circuit according to a first embodiment of the present invention.

FIG. 2 is a circuit diagram showing a modification of the output control circuit according to the first embodiment of the present invention.

FIG. 3 is a circuit diagram showing an output control circuit according to a second embodiment of the present invention.

FIG. 4 is a circuit diagram showing an output control circuit according to a third embodiment of the present invention.

FIG. 5 is a circuit diagram showing an output control circuit according to a fourth embodiment of the present invention.

FIG. 6 is a circuit diagram showing an output control circuit according to a fifth embodiment of the present invention.

FIG. 7 is a circuit diagram showing a modification of the output control circuit according to the fifth embodiment.

FIG. 8 is a circuit diagram showing another modification of the output control circuit according to the fifth embodiment.

FIG. 9 is a diagram showing an image of a layout for the output control circuit of the first embodiment.

FIG. 10 is a diagram showing another image of a layout for the output control circuit of the first embodiment.

FIG. 11 is a diagram showing an image of a layout for the output control circuit of the third embodiment.

FIG. 12 is a diagram showing an image of another layout for the output control circuit of the third embodiment.

FIG. 13 is a circuit diagram showing a conventional output control circuit.

### DESCRIPTION OF THE PREFERRED EMBODIMENTS

The preferred embodiments of the present invention will now be described while referring to drawings. In the following embodiments, the transmitter of an interface circuit is employed as an output control circuit according to the present invention. However, the present invention can also be applied for another example interface circuit. It should be noted that to simplify the explanation a buffer circuit and other components are not shown in the drawings.

### First Embodiment

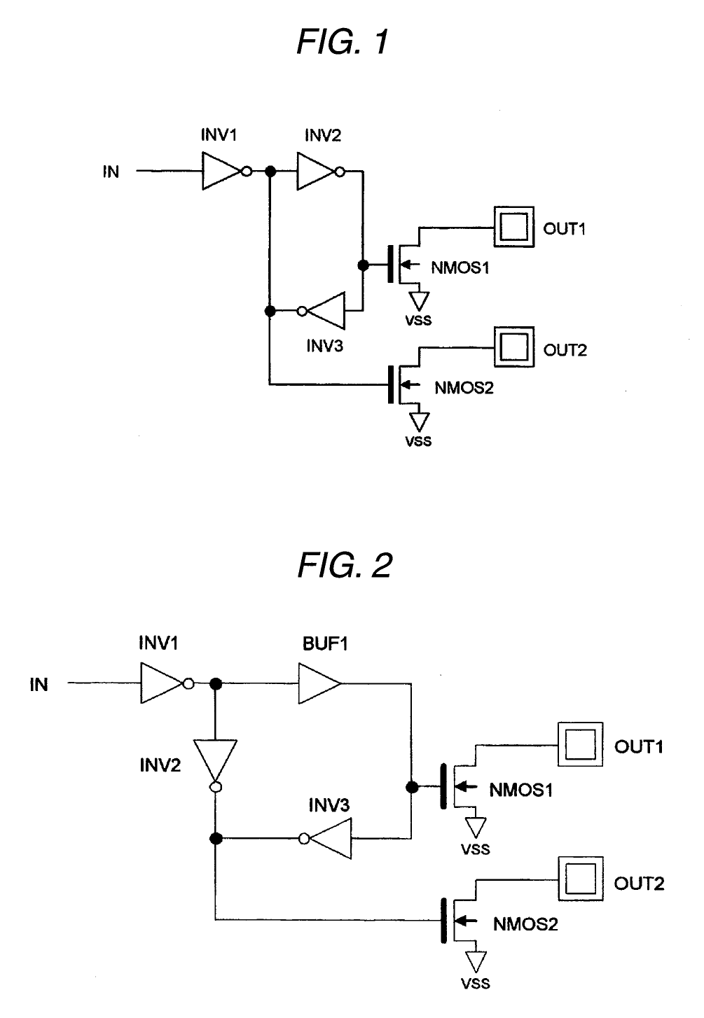

FIG. 1 is a circuit diagram showing an output control circuit according to a first embodiment of the present invention. As shown in FIG. 1, the output control circuit of the first embodiment includes: one input terminal; two output terminals OUT1 and OUT2; three inverters INV1, INV2 and INV3 that are connected in series; and two output transistors NMOS1 and NMOS2. It should be noted that each of the inverters INV1, INV2 and INV3 is a CMOS inverter obtained by the connection, in series, of an NMOS transistor and a PMOS transistor.

A signal IN input at the input terminal is transmitted to the inverter INV1. Then, the output of the inverter INV1 is transmitted to the inverter INV2, and the output of the inverter INV2 is transmitted to the inverter INV3. Thereafter, the output terminal of the inverter INV1 is connected to the output terminal of the inverter INV3. Thus, the voltage output by the inverter INV1 and the voltage output by the inverter INV3 are applied to the gate of the output transistor NMOS2. Further, the voltage output by the inverter INV2 is applied to the gate of the output transistor NMOS1. While the drain of the output transistor NMOS1 serves as the output terminal OUT1, and the drain of the output transistor NMOS2 serves as the output terminal OUT2.

The operation of the output control circuit of this embodiment will now be described. During the initial state, when the level of the voltage for the input signal IN is L (LOW), the level of the output voltage for the inverter INV1 is H (HIGH), the level of the output voltage at the inverter INV2 is L, and the level of the output voltage at the inverter INV3 is H. At this time, since a voltage at level L is applied to the gate of the output transistor NMOS1, and a voltage at level H is applied to the gate of the output transistor NMOS2, the state of the output transistor NMOS1 is OFF, and the state of the output transistor NMOS 2 is also OFF. As a result, a signal is output by the output terminal OUT2. During this initial state, since the output voltage of the inverter INV1 is at the same level as the output voltage of the inverter INV3, a lead-through current does not flow between the inverters INV1 and INV3.

When during the initial state the level of the voltage at the input signal IN is changed to H, the level of the output voltage at the inverter INV1 goes to L. However, the level of the output voltage of the inverter INV2 does not immediately go to H because of the delay at the inverter INV2, and remains at level L throughout the delay period at the inverter INV2. Therefore, the OFF state at the output transistor NMOS1 is maintained so long as the delay period at the inverter INV2 is continued.

When the level of the output voltage at the inverter INV2 is L, the level of the output voltage at the inverter INV3 is H. As described above, since the output terminal of the inverter INV1 is connected to the output terminal of the inverter INV3, during the state wherein the level of the output voltage of the inverter INV1 is L and the level of the output voltage of the inverter INV3 is H, a lead-through current flows from the inverter INV3 to the inverter INV1, and it is not easy for the gate voltage of the output transistor NMOS2 to be dropped. That is, when the output voltage of the inverter INV1 goes to level L, the output transistor NMOS2 is not immediately rendered off, and the ON state is maintained.

When the delay period for the inverter INV2 has elapsed, and when the level of the output voltage for the inverter INV2 is changed to H and the state of the output transistor NMOS1 is shifted to ON, the level of the output voltage for the inverter INV3 goes L. At this time, the output voltage level of the inverters INV1 and INV3 go to L, and accordingly, the output transistor NMOS2 is rendered off. As described above, almost simultaneously with the shifting to ON of the state for the output transistor NMOS1, the state of the output transistor NMOS2 is shifted to OFF.

An explanation has been given for the operation performed by the output control circuit when the level of the voltage for the input signal IN is changed from L to H. This same operation is performed when the level of the voltage for the input signal IN is changed from H to L. That is, in this case, almost simultaneously with the shifting to OFF of the output transistor NMOS1, the state of the output transistor NMOS2 is shifted to ON.

According to the output control circuit of this embodiment, a delay difference between differential signals can be reduced without remarkably increasing the circuit size. Therefore, when the operating cycle of the output control circuit is reduced and the operating speed is increased, a stable operation can still be obtained.

FIG. 2 is a circuit diagram showing a modification of the output control circuit of the first embodiment. As shown in FIG. 2, an output control circuit for the modification of the first embodiment includes: one input terminal; two output terminals OUT1 and OUT2; two inverters INV1 and INV2 that are connected in series; a buffer BUF1 and an inverter INV3 that are connected, in parallel, to the inverter INV2; and two output transistors NMOS1 and NMOS2.

A signal IN received at the input terminal is transmitted to the inverter INV1. Then, the output of the inverter INV1 is transmitted to the inverters INV2 and the buffer BUF1, and the output of the BUF1 is transmitted to the inverter INV3. The output terminal of the inverter INV2 is connected to the output terminal of the inverter INV3. With this arrangement, the output voltage of the inverter INV2 and the output voltage of the inverter INV3 are applied to the gate of the output transistor NMOS2, and the output voltage of the buffer BUF1 is applied to the gate of the output transistor NMOS1. The drain of the output transistor NMOS1 serves as the output terminal OUT1, and the drain of the output transistor NMOS2 serves as the output terminal OUT2.

By using the output control circuit shown in FIG. 2, the delay difference between differential signals can also be reduced without remarkably increasing the circuit size. Therefore, when the operating cycle of the output control circuit is reduced and the operating speed is increased, a stable operation can be obtained.

### Second Embodiment

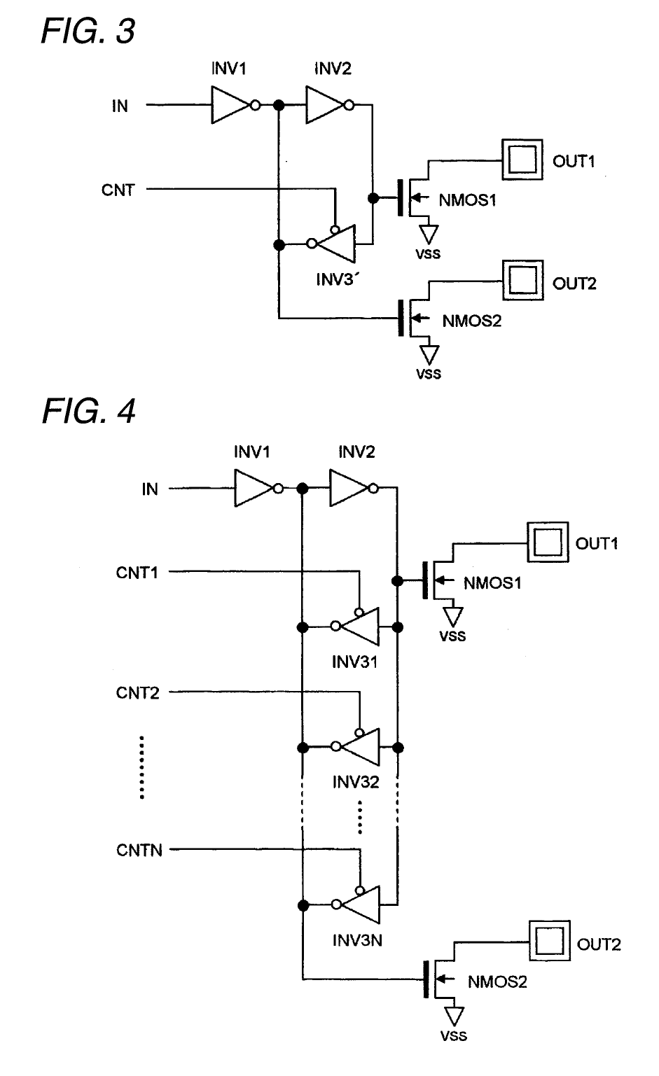

FIG. 3 is a circuit diagram showing an output control circuit according to a second embodiment of the present invention. The output control circuit for the second embodiment includes a tri-state inverter INV3′, instead of the inverter INV3 provided for the output control circuit for the first embodiment. The tri-state inverter INV3′ adjusts an output impedance using a control signal CNT.

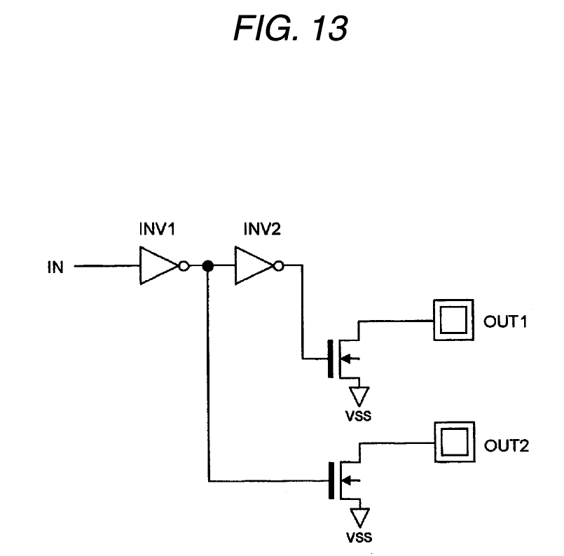

When the output impedance of the tri-state inverter INV3′ is increased based on the control signal CNT, the arrangement of the output control circuit is substantially the same as shown in FIG. 13. Therefore, in a case wherein there is a not very strict timing limitation, i.e., a case wherein a high-speed operation is not required, only the output impedance of the tri-state inverter INV3′ need be increased. Since a lead-through current does not flow when the output impedance of the tri-state impedance INV3′ is increased, power consumption can be reduced. And according to the output control circuit of this embodiment, a variable operating speed for an interface circuit can also be flexibly handled.

### Third Embodiment

FIG. 4 is a circuit diagram showing an output control circuit according to a third embodiment of the present invention. While the output control circuit for the second embodiment includes only one tri-state inverter INV3′, the output control circuit for the third embodiment includes, as shown in FIG. 4, a plurality of tri-state inverters INV31 to INV3N connected in parallel. In the output control circuit of this embodiment, the tri-state inverters INV31 to INV3N are individually controlled using control signals CNT1 to CNTN. With this arrangement, a delay difference between gate signals of output transistors can be more closely adjusted, without changing a semiconductor mask. Thus, not only is a reduction in power consumption obtained, but also a manufacturing cost reduction and an improved yield.

### Fourth Embodiment

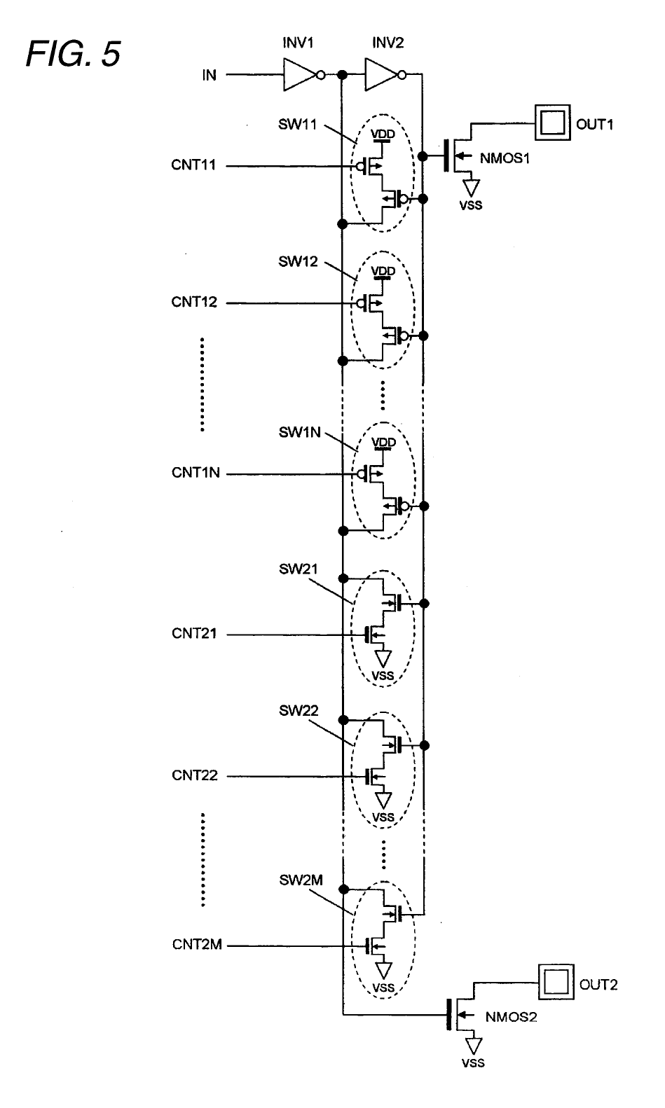

FIG. 5 is a circuit diagram showing an output control circuit according to a fourth embodiment of the present invention. The output control circuit of the fourth embodiment includes PMOS switches SW11 to SW1N and NMOS switches SW21 to SW2M, instead of the tri-state inverters INV31 to INV3N provided for the output control circuit of the third embodiment. Each of the PMOS switches SW11 to SW1N includes two P type MOS transistors connected in series, and each of the NMOS switches SW21 to SW2M includes two N type MOS transistors connected in series. The PMOS switches SW11 to SW1N are independently controlled based on control signals CNT11 to CNT1N, and the NMOS switches SW21 to SW2M are independently controlled based on control signals CNT21 to CNT2M. As a result of the control provided by using the control signals CNT11 to CNT1N and CNT21 to CNT2M, the voltage on the output of the inverter INV1 can be closely controlled.

Since the PMOS switches SW11 to SW1N and the NMOS switches SW21 to SW2M are individually controlled, a delay difference between the gate signals of the output transistors NMOS1 and NMOS2 can be adjusted at the rise and the tail of each gate signal. Furthermore, since manufacturing variations have increased due to the recent development of micromachining for the semiconductor manufacturing process and variations between PMOS transistors and NMOS transistors tend to occur without any correlation, it is highly preferable that the PMOS (the PMOS switches SW11 to SW1N) and the NMOS (NMOS switches SW21 to SW2M) be separately and finely adjusted.

### Fifth Embodiment

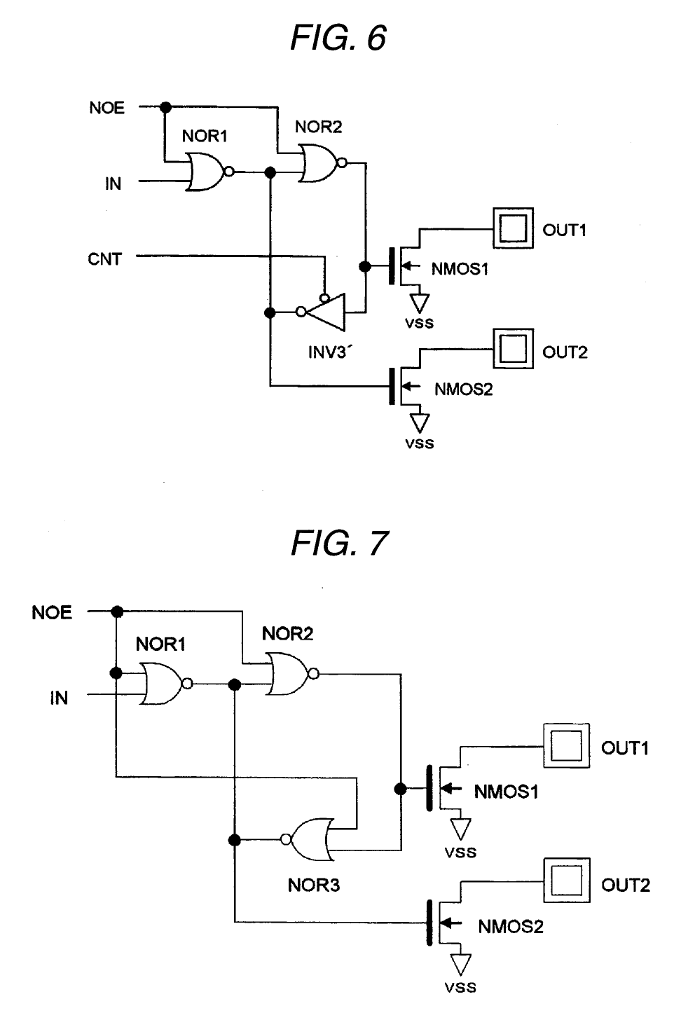

FIG. 6 is a circuit diagram showing an output control circuit according to a fifth embodiment of the present invention. The output control circuit for the fifth embodiment includes NOR gates NOR1 and NOR2, connected in series, instead of the inverters INV1 and INV2 provided for the output control circuit of the second embodiment, and to control these NOR gates a NOE signal is used. With this arrangement, when a sleeve mode for an interface circuit is designated, the gates of output transistors NMOS1 and NMOS2 can be controlled based on control signals NOE and CNT. As a result, power consumption waste and an erroneous operation can be prevented. Simply to control the gates of the output transistors NMOS1 and NMOS2, only the control signal NOE may be employed, as shown in FIG. 7.

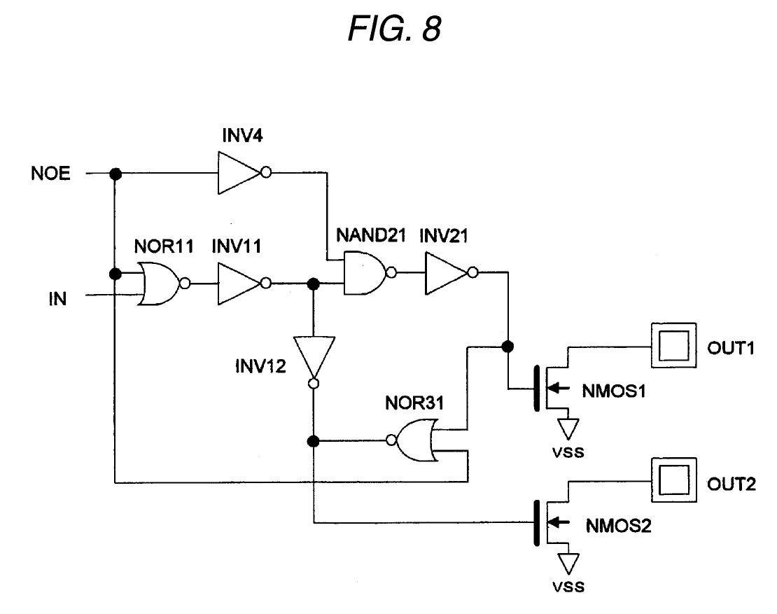

However, generally, the individual transistors included in inverters are gradually larger as they are close to the output transistor, and when a NOR gate to be connected directly to an output transistor is employed, the dimension of the circuit would be increased. Therefore, the arrangement can be changed to that shown in FIG. 8. With the arrangement shown in FIG. 8, since the circuits connected directly to the output transistors NMOS1 and NMOS2 are inverters, the scale of the circuit can be smaller than that in FIG. 7, and a more practical arrangement can be obtained.

An explanation will now be given for the layout, on a substrate, of the inverters and the output transistors included in the output control circuit for the above-described embodiments. As micromachining for the semiconductor manufacturing process has been developed, the characteristic change of a circuit due to the circuit layout, such as the arrangement or the shapes of transistors, has increased. Therefore, not only circuit design, but also the layout should be taken into account.

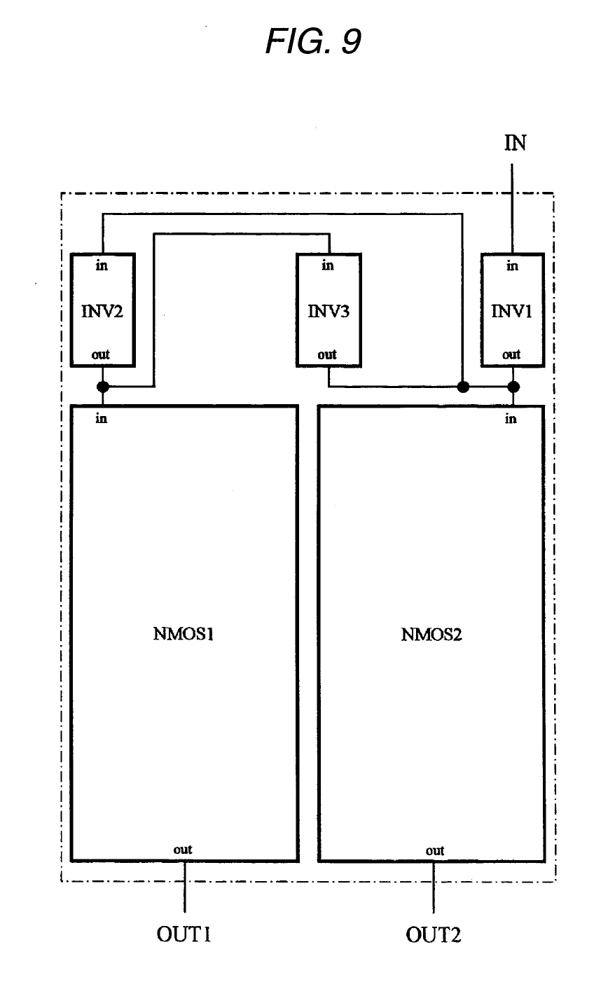

FIG. 9 is a diagram showing an image for the layout of the output control circuit of the first embodiment. It is preferable that, in so far as possible, the output transistors NMOS1 and NMOS2 have the same shapes, so that signals output by the output terminals OUT1 and OUT2 are synchronized with each other. It is also preferable that, in so far as possible, the lengths of the wiring to be connected to the gates of the output transistors NMOS1 and NMOS2 be equal. Furthermore, since the input terminal of the inverter INV3 is connected to the output terminal of the inverter INV2, and the output terminal of the inverter INV3 is connected to the output terminal of the inverter INV1, to efficiently perform the wiring, the inverter INV3 should be located between the inverters INV1 and INV2. Similarly, in order to efficiently perform the wiring for the arrangement in FIG. 8, the NOR gate NOR31 should be located between the inverters INV12 and INV21, which are directly connected to the output transistors NMOS1 and NMOS2.

In addition, since the output control circuit for the first embodiment includes two output transistors, an area equivalent in size to two cells is required. And it is preferable that two cells be adjacently arranged in order to synchronize individual output signals. Further, it is more effective for an area equivalent to two cells to be employed for a layout for one cell, because, judging from experience, a reduction in the area dimensions can be easily achieved.

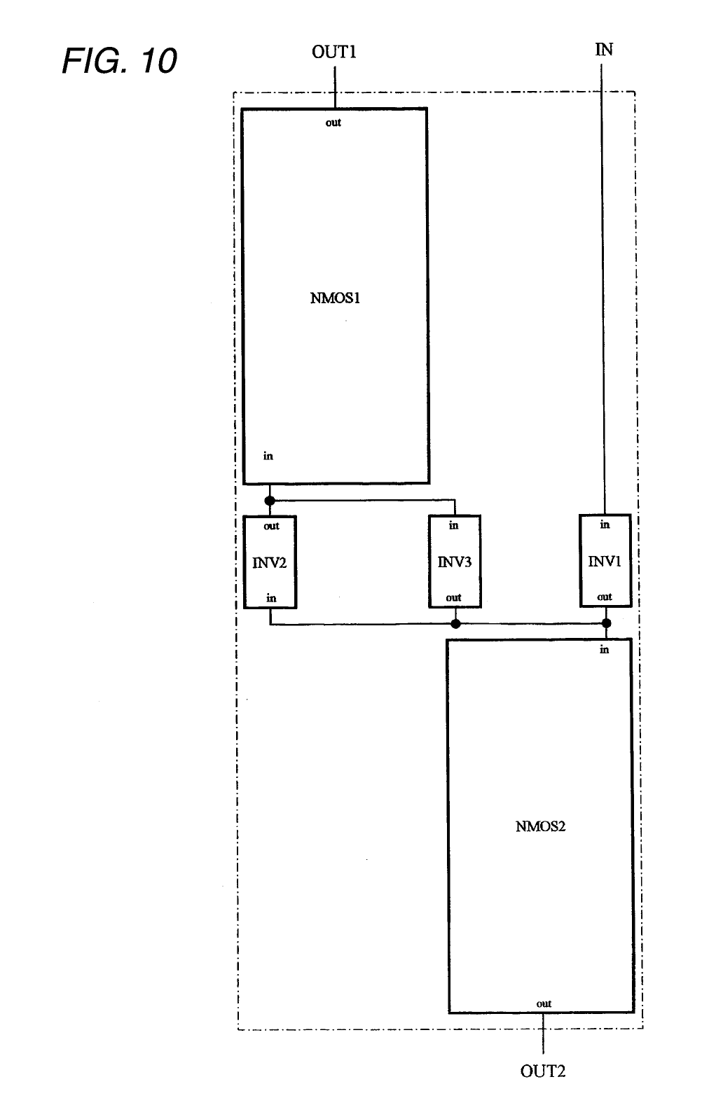

Moreover, while taking into account the affect due to wiring that is extended from a cell to a pad, the arrangement shown in FIG. 9 is satisfactory in a case wherein pads are arranged in a row. However, when pads are arranged vertically, in two rows, cells corresponding to the output transistors NMOS1 and NMOS2 should be arranged vertically, as shown in FIG. 10, so that the affect due to wiring that is extended from the cell to the pads can be equally distributed. The layouts shown in FIGS. 9 and 10 can also be applied for the output control circuits for the second to the fifth embodiments.

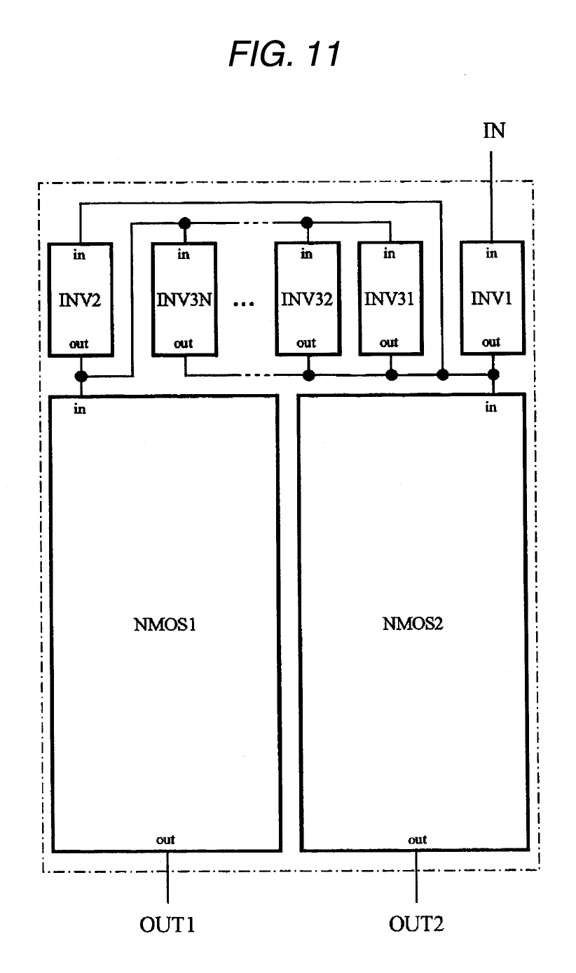

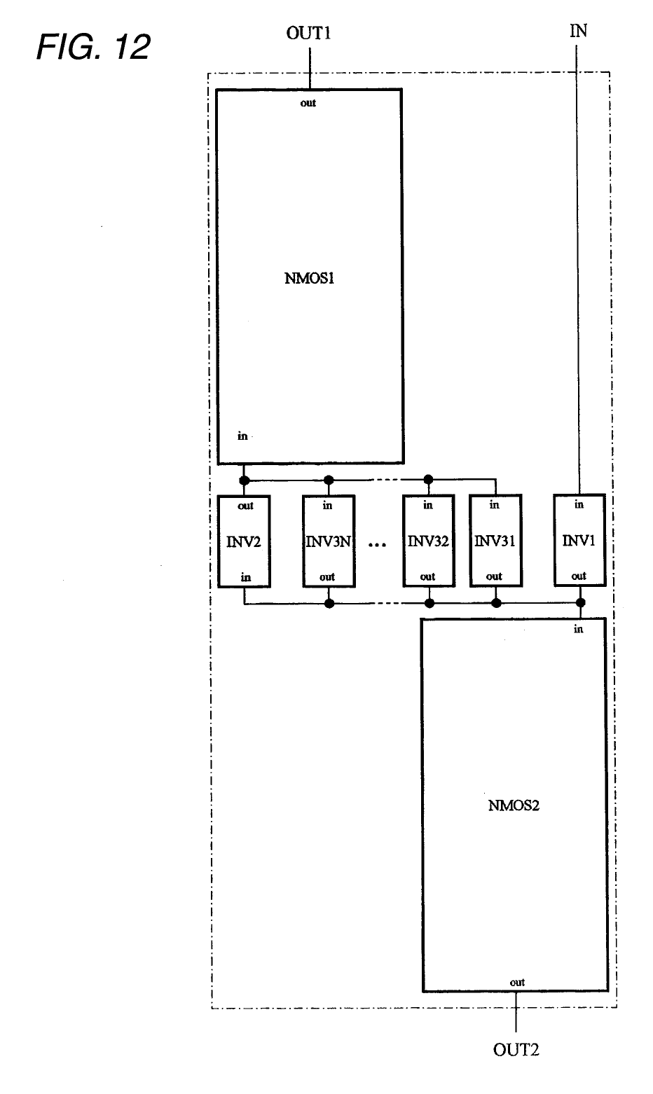

FIG. 11 is a diagram showing an image for a layout of the output control circuit for the third embodiment. When the tri-state inverters INV31 to INV3N are arranged between the inverters INV1 and INV2, the wiring can be efficiently performed. Furthermore, two cells are adjacently arranged. It should be noted that when pads are located vertically, in two rows, individual cells corresponding to the output transistors NMOS1 and NMOS2 may be arranged vertically, as shown in FIG. 12.

The output control circuit according to the present invention, for which the scale of the circuit is small, still operates stably at high speed, and is useful as an interface that employs differential signals.

1. (canceled)

2. An output control circuit comprising:
a first inverter and a second inverter, connected in series, for outputting signals at an inverted voltage level of an input signal;
a first buffer, for outputting a signal at a voltage level of a signal output by the first inverter;
a first output unit, for which output is controlled based on the voltage level of the signal output by the first buffer;
a third inverter, an output of which is connected to an output of the second inverter, for outputting a signal at an inverted voltage level of a signal output by the first buffer; and
a second output unit, for which output is controlled based on a voltage level of a signal output by the second inverter and a voltage level of a signal output by the third inverter.

3. (canceled)

4. The output control circuit according to claim 2, wherein one of the first to the third inverters, or the first buffer, includes a NAND gate or a NOR gate, and receives a signal different from the input signal.

5. (canceled)

6. The output control circuit according to claim 2, wherein CMOS inverters are employed as inverters whose outputs are directly connected to the first output unit and as inverters whose outputs are directly connected to the second output unit.

7. (canceled)

8. The output control circuit according to claim 2, wherein the third inverter is a tri-state inverter for which output impedance is controlled based on a control signal.

9. (canceled)

10. The output control circuit according to claim 2, wherein the third inverter is a switch whose output current capacity is controlled based on a control signal.

11. (canceled)

12. The output control circuit according to claim 2, wherein the third inverter is arranged between the inverter whose output is directly connected to the first output unit and the inverter whose output is directly connected to the second output unit.

13. (canceled)

14. The output control circuit according to claim 2, wherein the inverter whose output is directly connected to the first output unit is arranged so as to be nearer the first output unit than the inverter, whose output is directly connected to the second output unit, or the third inverter.

15. (canceled)

16. The output control circuit according to claim 2, wherein the inverter whose output is directly connected to the second output unit is arranged so as to be nearer the second output unit than the inverter, whose output is directly connected to the first output unit, or the third inverter.

17. (canceled)

18. The output control circuit according to claim 2, further comprising:
a first pad connected to an output terminal of the first output unit; and
a second pad connected to an output terminal of the second output unit, wherein the first pad and the second pad are adjacently arranged.
